(19) United States
(12) Patent Application Publication
(10) Pub. No.: US 2025/0174467 A1
(43) Pub. Date: May 29, 2025

(54) SUBSTRATE PROCESSING APPARATUS AND SUBSTRATE PROCESSING METHOD

(71) Applicant: SEMES CO., LTD., Cheonan-si (KR)

(72) Inventors: Min Jung KIM, Bucheon-si (KR); Moon Sik CHOI, Cheonan-si (KR); Sul LEE, Cheonan-si (KR)

(73) Assignee: SEMES CO., LTD., Cheonan-si, Chungcheongnam-do (KR)

(21) Appl. No.: 18/931,883

(22) Filed: Oct. 30, 2024

(30) Foreign Application Priority Data
Nov. 24, 2023 (KR) 10-2023-0165727

(51) Int. Cl. H01L 21/3213; H01L 21/67

(52) U.S. Cl. CPC H01L 21/32134; H01L 21/6708

(57) ABSTRACT

Disclosed is a substrate processing method including: loading a substrate onto a support unit positioned in a processing space of a chamber so that a patterned face of the substrate faces down; and rotating the substrate loaded onto the support unit, discharging an etchant for etching a thin film formed on the patterned face onto the patterned face of the substrate, and discharging a heating fluid onto a non-patterned face of the substrate.

### CROSS-REFERENCE TO RELATED APPLICATIONS

This application claims priority to and the benefit of Korean Patent Application No. 10-2023-0165727 filed in the Korean Intellectual Property Office on Nov. 24, 2023, the entire contents of which are incorporated herein by reference.

### TECHNICAL FIELD

The present invention relates to a substrate processing apparatus and a substrate processing method.

### BACKGROUND ART

In general, in a process of processing a glass substrate or a wafer in a process of manufacturing a flat panel display device or a semiconductor, various processes, such as a photoresist coating process, a developing process, an etching process, and an ashing process, are performed.

Among them, the etching process or the cleaning process is a process for removing unnecessary regions from a thin film formed on a substrate, and high selectivity for the thin film, high etch rate, and etch uniformity are required, and higher levels of etch selectivity and etch uniformity are required as semiconductor devices are highly integrated.

However, in an existing etching process or cleaning process, the etch rate uniformity (E/R Uniformity) is significantly reduced due to the temperature difference between the center and the edge of the substrate. In particular, when BHDIW (back high temperature pure water) is supplied to the rear surface of the substrate and a treatment solution is discharged to the front surface of the substrate, the etch rate uniformity (E/R Uniformity) is further reduced when the temperature difference between the center and the outer side of the substrate exceeds a certain level.

### SUMMARY OF THE INVENTION

The present invention has been made in an effort to provide a substrate processing apparatus and method capable of improving etch performance.

The present invention has also been made in an effort to provide a substrate processing apparatus and method for uniformly distributing Etch Rate (ER).

The present invention has also been made in an effort to provide a substrate processing apparatus and method capable of compensating for a temperature decrease that is a factor of a decrease in an ER by region on a substrate.

The object of the present invention is not limited thereto, and other objects not mentioned will be clearly understood by those of ordinary skill in the art from the following description.

An exemplary embodiment of the present invention provides a substrate processing method including: loading a substrate onto a support unit positioned in a processing space of a chamber so that a patterned face of the substrate faces down; and rotating the substrate loaded onto the support unit, discharging an etchant for etching a thin film formed on the patterned face onto the patterned face of the substrate, and discharging a heating fluid onto a non-patterned face of the substrate.

Further, the heating fluid may be discharged to an impact point deviating from a center of the substrate such that a temperature of an edge region of the substrate is higher than a temperature of a center region of the substrate by a predetermined temperature, and the etchant may be discharged onto a center of the substrate.

Further, the impact point may be spaced from an edge of the substrate.

Further, the heating fluid may be discharged onto the non-patterned face of the substrate at a predetermined temperature higher than a temperature of the etchant by a predetermined temperature.

Further, the heating fluid may be discharged to a plurality of impact points deviating from the center of the substrate, and the impact point may be provided closer to an edge of the substrate than to a center of the substrate.

Further, the plurality of impact points may include a first impact point and a second impact point, and the first impact point and the second impact point may be provided to be symmetrical with respect to the center of the substrate.

Further, the substrate may be inverted by an inversion unit after being loaded into the chamber, and loaded onto the support unit.

Further, the substrate may be inverted by an inversion unit located in a separate chamber before being loaded into the chamber and loaded onto the support unit.

Further, the thin film may be a titanium nitride (TiN) film, the etchant may include hydrogen peroxide, and the heating unit may include high temperature pure water.

Another exemplary embodiment of the present invention provides a substrate processing apparatus including: a chamber providing a processing space; a support unit provided in the processing space, and for supporting and rotating a substrate with a patterned face of the substrate facing down; an etchant supply unit for discharging an etchant from a lower portion of the substrate supported on the support unit toward the patterned face of the substrate; and a heating fluid supply unit for discharging a heating fluid from an upper portion of the substrate supported on the support unit toward a non-patterned face of the substrate.

Further, the heating fluid supply unit may discharge the heating fluid to an impact point deviating from a center of the substrate such that a temperature of an edge of the substrate is higher than a temperature of the center of the substrate by a predetermined temperature.

Further, the heating fluid supply unit may discharge the heating fluid to an impact point located closer to the edge than the center of the substrate.

Further, the heating fluid supply unit may discharge the heating fluid heated to a predetermined temperature higher than a temperature of the etchant to the non-patterned face of the substrate.

Further, the heating fluid supply unit may include a first nozzle and a second nozzle, and an impact point of the first nozzle and an impact point of the second nozzle may be provided to be symmetrical with respect to the center of the substrate.

Further, the etchant may contain hydrogen peroxide, and the heating fluid may include high-temperature pure water.

Further, the substrate processing apparatus may further include an inversion unit for inverting the substrate so that the patterned face of the substrate faces down and the non-patterned face of the substrate faces up.

Further, the support unit may include: a support plate having a diameter larger than the substrate; support pins protruding from a top surface of the support plate and supporting the substrate; and chuck pins provided at an edge portion of the support plate and supporting a lateral portion of the substrate when the substrate is rotated.

Still another exemplary embodiment of the present invention provides a substrate processing method including: loading a substrate onto a support unit positioned in a processing space of a chamber so that a patterned face of a substrate faces down; and rotating the substrate loaded onto the support unit, discharging an etchant for etching a thin film on a patterned face of the substrate to the patterned face of the substrate, and discharging a heating fluid onto a non- patterned face of the substrate, in which the heating fluid is discharged to an impact point provided closer to an edge of the substrate than to a center of the substrate, the etchant is discharged to the center of the substrate, and the heating fluid has a temperature higher than the etchant.

Further, the heating fluid may be discharged to a plurality of impact points deviating from the center of the substrate, and the plurality of impact points may include a first impact point and a second impact point, and the first impact point and the second impact point may be provided to be symmetrical with respect to the center of the substrate.

Further, the substrate may be inverted by an inversion unit after being loaded into the chamber and loaded onto the support unit, or may be inverted by the inversion unit located in a separate chamber before being loaded into the chamber and loaded onto the support unit.

According to the exemplary embodiments of the present invention, etching performance may be improved.

According to the exemplary embodiments of the present invention, the distribution of Etch Rate (ER) may be made uniform.

According to the exemplary embodiments of the present invention, the temperature decrease, which is a factor of the decrease in Etch Rate (ER) by region on the substrate, may be supplemented.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view schematically illustrating a substrate processing facility provided with a substrate processing apparatus according to an exemplary embodiment of the present invention.

FIG. 2 is a top plan view of the substrate processing apparatus of FIG. 1.

FIG. 3 is a cross-sectional view of the substrate processing apparatus of FIG. 1.

FIG. 4 is a diagram illustrating an inversion unit illustrated in FIGS. 2 and 3.

FIGS. 5 and 6 are flowcharts and diagrams illustrating a process of processing a substrate according to an exemplary embodiment of the present invention.

FIG. 7 is a diagram illustrating a modified example of the present invention.

FIG. 8 is a graph illustrating the uniformity of etch rate (E/R Uniformity) through inverse supply.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

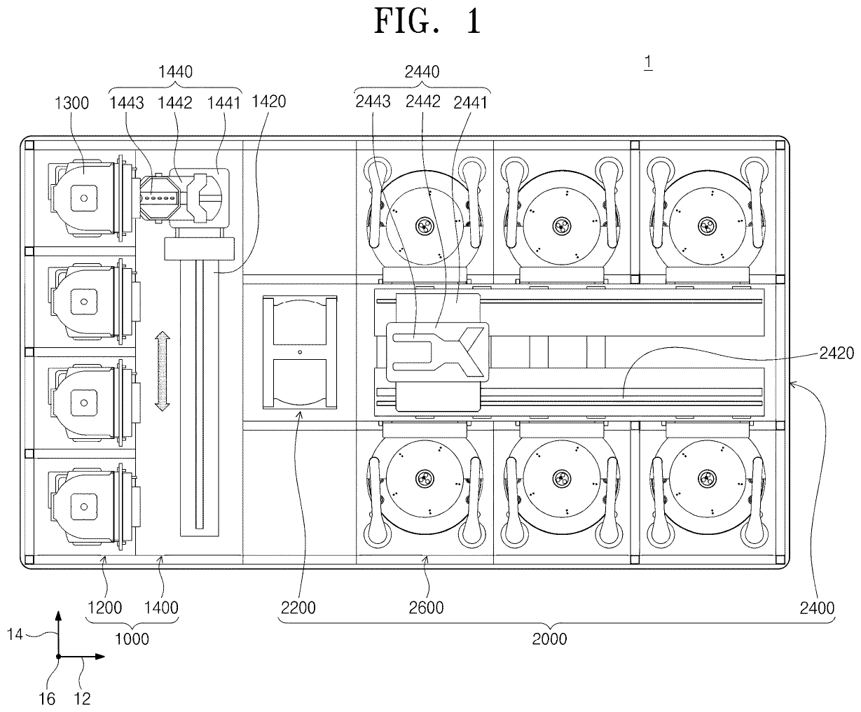

FIG. 1 is a top plan view schematically illustrating a substrate processing facility 1 of the present invention.

Referring to FIG. 1, substrate processing equipment 1 includes an index module 1000 and a process processing module 2000. The index module 1000 includes a load port 1200 and a transfer frame 1400. The load port 1200, the transfer frame 1400, and the process processing module 2000 are sequentially arranged in series. Hereinafter, a direction in which the load port 1200, the transfer frame 1400, and the process processing module 2000 are arranged is referred to as a first direction 12. When viewed above, a direction vertical to the first direction 12 is referred to as a second direction 14, and a direction vertical to a plane including the first direction 12 and the second direction 14 is referred to as a third direction 16.

A carrier 1300 in which a substrate W is accommodated is seated on the load port 1200. The load port 1200 is provided in plurality, and the plurality of load ports 120 is arranged in series in the second direction 14. FIG. 1 illustrates that four load ports 1200 are provided. However, the number of load ports 1200 may also be increased or decreased according to process efficiency of the process processing module 2000 and a condition, such as foot print. A slot (not illustrated) provided to support an edge of the substrate W is formed in the carrier 1300. The slot is provided in plurality in the third direction 16. The substrates W are positioned in the carrier 1300 to be stacked while being spaced apart from each other in the third direction 16. As the carrier 1300, a Front Opening Unified Pod (FOUP) may be used.

The process processing module 2000 includes a buffer unit 2200, a transfer chamber 2400, and a process chamber 2600. A longitudinal direction of the transfer chamber 2400 is parallel to the first direction 12. Process chambers 2600 are disposed at one side and the other side of the transfer chamber 2400 in the second direction 14. The process chambers 2600 positioned at one side of the transfer chamber 2400 and the process chambers 2600 positioned at the other side of the transfer chamber 2400 are provided to be symmetric to each other based on the transfer chamber 2400. Some of the process chambers 2600 are disposed in the longitudinal direction of the transfer chamber 2400. Further, some of the process chambers 2600 are disposed to be stacked with each other. That is, the process chambers 2600 may be disposed in an arrangement of A×B (A and B are natural numbers equal to or greater than 1) at one side of the transfer chamber 2400. Herein, A is the number of process chambers 2600 provided in series in the first direction 12, and B is the number of process chambers 2600 provided in series in the third direction 16. When four or six process chambers 2600 are provided at one side of the transfer chamber 2400, the process chambers 2600 may be disposed in an arrangement of 2×2 or 3×2. The number of process chambers 2600 may be increased or decreased. Contrast to the foregoing, the process chambers 2600 may be provided only at one side of the transfer chamber 2400. Further, contrast to the foregoing, the process chambers 2600 may be provided only at one side and both sides of the transfer chamber 2400 in a single layer.

The buffer unit 2200 is disposed between the transfer frame 1400 and the transfer chamber 2400. The buffer unit 2200 provides a space in which the substrate W stays before the substrate W is transferred between the transfer chamber 2400 and the transfer frame 1400. The buffer unit 2200 is provided with slots (not illustrated) on which the substrate W is placed therein, and the slots (not illustrated) are provided in plurality so as to be spaced apart from each other in the third direction 16. In the buffer unit 2200, a surface facing the transfer frame 1400 and a surface facing the transfer chamber 2400 are opened.

The transfer frame 1400 transfers the substrate W between the carrier 1300 seated on the load port 1200 and the buffer unit 2200. In the transfer frame 1400, an index rail 1420 and an index robot 1440 are provided. A longitudinal direction of the index rail 1420 is provided to be parallel to the second direction 14. The index robot 1440 is installed on the index rail 1420, and linearly moves in the second direction 14 along the index rail 1420. The index robot 1440 includes a base 1441, a body 1442, and an index arm 1443. The base 1441 is installed to be movable along the index rail 1420. The body 1442 is coupled to the base 1441. The body 1442 is provided to be movable in the third direction 16 on the base 1441. Further, the base 1442 is provided to be rotatable on the base 1441. The index arm 1443 is coupled to the body 1442, and is provided to be movable forward and backward with respect to the body 1442. A plurality of index arms 1443 is provided to be individually driven. The index arms 1443 are arranged to be stacked while being spaced apart from each other in the third direction 16. Some of the index arms 1443 may be used when the substrate W is transferred from the process processing module 2000 to the carrier 1300, and the other may be used when the substrate W is transferred from the carrier 1300 to the process processing module 2000. This may prevent particles generated from the substrate W before the process processing from being attached to the substrate W after the process processing in the process of loading and unloading the substrate W by the index robot 1440.

The transfer chamber 2400 transfers the substrate W between the buffer unit 2200 and the process chamber 2600, and between the process chambers 2600. A guide rail 2420 and a main robot 2440 are provided to the transfer chamber 2400. The guide rail 2420 is disposed so that a longitudinal direction thereof is parallel to the first direction 12. The main robot 2440 is installed on the guide rail 2420, and linearly moves on the guide rail 2420 in the first direction 12. The main robot 2440 includes a base 2441, a body 2442, and a main arm 2443. The base 2441 is installed to be movable along the guide rail 2420. The body 2442 is coupled to the base 2441. The body 2442 is provided to be movable in the third direction 16 on the base 2441. Further, the base 2442 is provided to be rotatable on the base 2441. The main arm 2443 is coupled to the body 2442, and is provided to be movable forward and backward with respect to the body 2442. A plurality of main arms 2443 is provided to be individually driven. The main arms 2443 are arranged to be stacked while being spaced apart from each other in the third direction 16. The main arm 2443 used when the substrate W is transferred from the buffer unit 2200 to the process chamber 2600 may be different from the main arm 2443 used when the substrate W is transferred from the process chamber 2600 to the buffer unit 2200.

A substrate processing apparatus 10 for performing a cleaning process on the substrate W is provided in the process chamber 2600. The substrate processing apparatus 10 provided in each process chamber 2600 may have a different structure according to the type of washing process performed. Optionally, the substrate processing apparatus 10 in each process chamber 2600 may have the same structure. Optionally, the process chambers 2600 may be divided into a plurality of groups, and the substrate processing apparatuses 10 provided in the process chambers 2600 included in the same group may have the same structure, and the substrate processing apparatuses 10 provided in the process chambers 2600 included in the different groups may have the different structures. For example, when the process chambers 2600 are divided into two groups, the process chambers 2600 of a first group may be provided to one side of the transfer chamber 2400, and the process chambers 2600 of a second group may be provided to the other side of the transfer chamber 2400. Optionally, at each of the one side and the other side of the transfer chamber 2400, the process chambers 2600 of the first group may be provided to a lower layer, and the process chambers 2600 of the second group may be provided to an upper layer. The process chambers 2600 of the first group and the process chambers 2600 of the second group may be classified according to the type of chemical used or the type of cleaning method.

In the exemplary embodiment below, an apparatus for liquid-treating the substrate W by using treatment solutions, such as high-temperature sulfuric acid, high-temperature phosphoric acid, alkaline chemical solution, acidic chemical solution, rinsing solution, and drying gas, will be described as an example. However, the technical spirit of the present invention is not limited thereto, and may be applied to various types of devices performing a process while rotating the substrate W, such as an etching process.

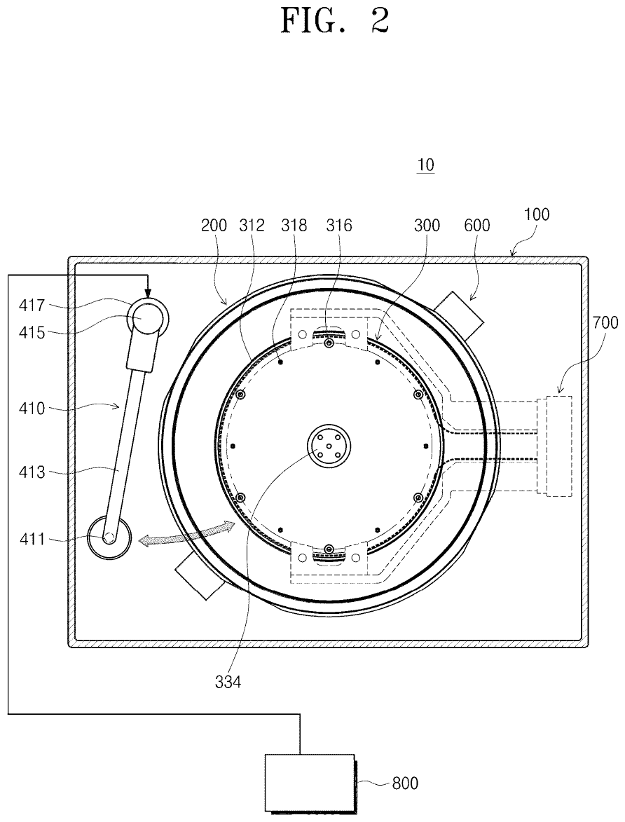

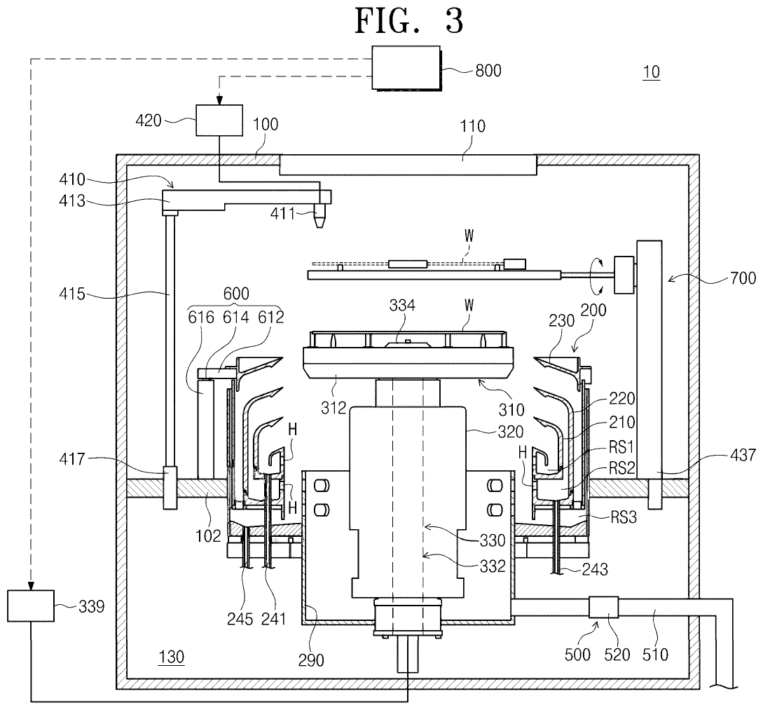

FIG. 2 is a top plan view of the substrate processing apparatus of FIG. 1, and FIG. 3 is a cross-sectional view of the substrate processing apparatus of FIG. 1. In FIG. 2, an inversion unit is illustrated as a dotted line.

Referring to FIGS. 2 and 3, the substrate processing apparatus 10 may include a chamber 100, a bowl 200, a support unit 300, a treatment solution supply unit 330, a heating fluid supply unit 410, an exhaust unit 500, a lifting unit 600, an inversion unit 700, and a controller 800.

The chamber 100 provides a sealed inner space. An airflow supply member 110 is installed on an upper portion of the chamber 100. The airflow supply member 110 forms a descending airflow in the chamber 100.

The airflow supply member 110 filters high-humidity external air and supplies the filtered external air into the chamber 100. The high-humidity external air passes through the airflow supply member 110 and is supplied into the chamber 100 to form descending airflow. The descending airflow provides uniform airflow to the upper portion of the substrate W, and discharges contaminant materials generated in the process of processing the surface of the substrate W by the treatment solution to the exhaust unit 500 through recovery containers 210,220, and 230 of the bowl 200 together with air.

The chamber 100 is divided into a process area 120 and a maintenance and repair region 130 by a horizontal partition wall 102. In the process region 120, the bowl 200 and the support unit 300 are located. In the maintenance and repair region 130, in addition to the recovery lines 241, 243, 245 and the exhaust line 510 connected to the bowl 200, a driving unit of the lifting unit 600, a driving unit connected to the treatment solution supply unit 410, supply lines, and the like are located. The maintenance and repair region 130 is isolated from the process region 120.

The bowl 200 has a cylindrical shape having an open upper portion, and has a processing space for processing the substrate W. The opened upper surface of the bowl 200 is provided as a loading and unloading passage of the substrate W. The support unit 300 is located in the processing space. The support unit 300 rotates the substrate W in the state of supporting the substrate W during the progress of the process.

The bowl 200 provides a lower space to which the exhaust duct 290 is connected at the lower end so that forced exhaust is made. In the bowl 200, the first to third recovery containers 210, 220, and 230 for introducing and sucking the treatment solution and gas scattered on the rotating substrate W are arranged in multiple stages.

The annular first to third recovery containers 210, 220, and 230 have exhaust ports H communicating with one common annular space. Specifically, each of the first to third recovery containers cylinders 210, 220, and 230 includes a bottom surface having an annular ring shape and a side wall extending from the bottom surface and having a cylindrical shape. The second recovery container 220 surrounds the first recovery container 210, and is spaced apart from the first recovery container 210. The third recovery container 230 surrounds the second recovery container 220, and is spaced apart from the second recovery container 220.

The first to third recovery containers 210, 220, and 230 provide first to third recovery spaces RS1, RS2, and RS3 into which an airflow containing the treatment solution and fumes scattered from the substrate W flows. The first recovery space RS1 is defined by the first recovery container 110, the second recovery space RS2 is defined by a spaced space between the first recovery container 210 and the second recovery container 120, and the third recovery space RS3 is defined by a spaced space between the second recovery container 120 and the third recovery container 130.

A central portion of each of the upper surfaces of the first to third recovery containers 210, 220, and 230 is opened. The first to third recovery containers 210, 220, and 230 are formed of inclined surfaces whose distance from the corresponding bottom surface gradually increases from the connected side walls toward the opened portion. The treatment solution scattered from the substrate W flows into the recovery spaces RS1, RS2, and RS3 along the upper surfaces of the first to third recovery containers 210, 220, and 230.

The first treatment solution introduced into the first recovery space RS1 is discharged to the outside through a first recovery line 241. The second treatment solution introduced into the second recovery space RS2 is discharged to the outside through a second recovery line 243. The third treatment solution introduced into the third recovery space RS3 is discharged to the outside through a third recovery line 245.

The exhaust unit 500 may exhaust the inside of the bowl 200. As an example, the exhaust unit 500 is to provide an exhaust pressure (suction pressure) to the recovery containers for recovering the treatment solution from among the first to third recovery containers 210, 220, and 230 during the process. The exhaust unit 500 includes an exhaust line 510 connected to an exhaust duct 290, and a damper 520. The exhaust line 510 receives exhaust pressure from an exhaust pump (not illustrated) and is connected with a main exhaust line embedded in a bottom space of a semiconductor production line.

In the meantime, the bowl 200 is coupled with the lifting unit 600 which changes a vertical position of the bowl 200. The lifting unit 600 linearly moves the bowl 200 in a vertical direction. According to the vertical movement of the bowl 200, a relative height of the bowl 200 with respect to the support unit 300 is changed.

The lifting unit 600 includes a bracket 612, a movement shaft 614, and a driver 616. The bracket 612 is fixedly installed on the outer wall of the processing container 100. The movement shaft 614 which moves in the vertical direction by the driver 616 is fixedly coupled to the bracket 612. When the substrate W is loaded in or unloaded from the support unit 300, the bowl 200 descends so that the support unit 300 protrudes above the bowl 200. In addition, the height of the bowl 200 is adjusted so that the treatment solution may be introduced into the predetermined recovery containers 210, 220, and 230 according to the type of the treatment solution supplied to the substrate W during the process. The bowl 200 may have different types of treatment solution and contaminated gas recovered for each recovery space RS1, RS2, and RS3.

The inversion unit 700 is a device for inverting the substrate. Herein, inverting refers to rotating the substrate W with the front face (patterned face) of the substrate facing up by 180° to face down, or rotating the substrate with the front face facing down by 180° to face up. Herein, the front face of the substrate is referred to as the patterned face, and the rear face of the substrate is referred to as the non-patterned face.

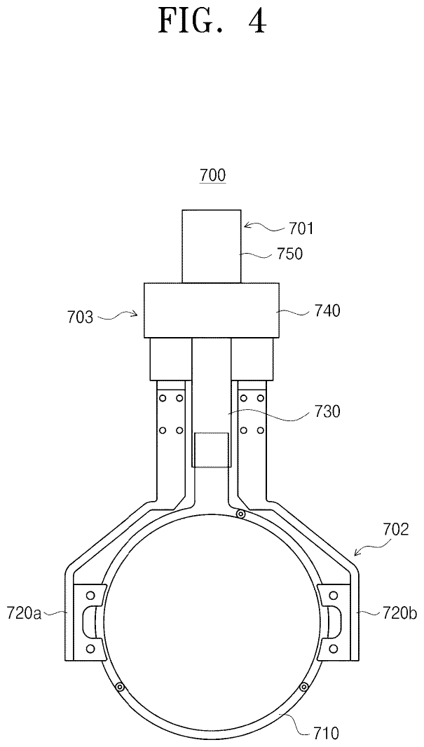

FIG. 4 is a diagram illustrating an inversion unit illustrated in FIGS. 2 and 3.

Referring to FIG. 4, the inversion unit 700 may include a vertical frame 701, an inversion part 702, and a transfer part 703. The vertical frame 701 is formed to be elongated in an up and down direction for transferring the substrate in the up and down direction. The vertical frame 701 supports the inversion part 702 and includes the transfer part 703.

The inversion part 702 may include a seating part 710, fixing arms 720a and 720b, a rotating part 740, and a support part 750. The seating part 710 has a circular ring shape for a substrate to be placed on. Preferably, the seating part 710 is formed somewhat larger than a diameter of the substrate. The seating part 710 is connected to an extension part 730 and fixed to the rotating part 740. The fixing arms 720a and 720b fix the substrate seated on the seating part 710. The fixing arms 720a and 720b are divided into two parts to chuck or unchuck the substrate. The distal ends of the fixing arms 720a and 720b are provided with gripping parts for gripping the substrate. The fixing arms 720a and 720b and the seating part 710 are connected to the rotating part 740. The rotating part 740 serves to invert the substrate and may include a rotating means for rotating the fixing arms 720a and 720b and the seating part 710. The support part 750 is coupled to the rotating part 740 to serve to support the substrate fixed by the fixing arms 720a and 720b and the seating part 710, and is coupled to the transfer part 703 formed on the frame 701 and is supported on the frame 701. The transfer part 703 moves the inversion part 702 up and down. On the other hand, the transfer part 703 is formed on the frame 701, and may move the inversion part 702 in the up and down direction by using a pneumatic actuator, and for further precise control, the transfer part may move the inversion part 702 by using a motorized device.

While in the present exemplary embodiment, it is illustrated that the inversion unit is provided within the substrate processing apparatus 10, the present invention is not limited thereto, and the inversion unit may be provided in a separate inversion chamber other than the chamber in which the etching process is performed. In this case, the substrate may be inverted in a separate inversion chamber and then loaded into the substrate processing apparatus.

Referring again to FIGS. 2 and 3, the support unit 300 supports the substrate W during the process and may rotate the substrate W during the process. The support unit 300 may include a support plate 310 and a spin drive unit 320.

The support plate 310 has a circular top surface. The support plate 310 is coupled to the spin drive unit 320 to rotate. The support plate 310 includes support pins 318. The support pins 318 may be spaced apart at predetermined intervals on the edges of the top surface of the support plate 310. The support pins 318 support the lower surface of the substrate W such that the substrate W is supported while being upwardly spaced apart from the support plate 310. Chucking pins 316 are installed on the edge of the support plate 310. The chucking pins 316 align the substrate W so that the substrate W supported by the plurality of support pins 318 is in its regular position. During the process, the chucking pins 316 come into contact with the lateral portion of the substrate W to prevent the substrate W from being separated from the regular position. The spin drive part 320 has a hollow shape and is coupled to the support plate 310 to rotate the support plate 310.

The treatment solution supply unit 330 is provided for spraying a treatment solution onto a thin film on the patterned face of the substrate. The treatment solution may be a high temperature chemical for etching the thin film on the surface of the substrate W.

In one example, the treatment solution supply unit 330 may include a nozzle body 334 and a back nozzle spraying part 334. The back nozzle spraying part 334 is positioned at the top center of the support plate 310. The back nozzle spraying part 334 discharges etchant onto the center of the patterned side of the substrate. The back nozzle spraying part 334 may spray a rinse solution (ultrapure water) in addition to the etchant. The nozzle body 332 penetrates and is axially mounted within the hollow spin drive unit 320. Although not illustrated, the interior of the nozzle body 334 may be provided with a treatment solution supply line and a rinse solution supply line. The back nozzle spraying part 334 is supplied with an etchant via an etchant supply part 339. According to the exemplary embodiment, the thin film may be a titanium nitride (TiN) film, and the etchant may include hydrogen peroxide or a mixture of hydrogen peroxide and an alkaline solution.

The heating fluid supply unit 410 may supply heating fluid to the non-patterned face of the substrate W such that a temperature of the edge region of the substrate W is higher than a temperature of the center region of the substrate.

The heating fluid supply unit 410 may include a first nozzle 411, a nozzle arm 413, a support rod 415, and a nozzle driver 417. The first nozzle 411 is supplied with heating fluid via a supply part 420. The first nozzle 411 discharges the heating fluid onto the non-patterned face of the substrate W. The nozzle arm 413 is an arm provided with a long length in one direction, and the first nozzle 411 is mounted at a leading end of the nozzle arm 413. The nozzle arm 413 supports the first nozzle 411. The support rod 413 is mounted to a rear end of the nozzle arm 415. The support rod 415 is located in the lower portion of the nozzle arm 413. The support rod 415 is disposed to be perpendicular to the nozzle arm 413. The nozzle driver 417 is provided at the lower end of the support rod 415. The nozzle driver 417 rotates the support rod 415 about the longitudinal direction axis of the support rod 415. With the rotation of the support rod 415, the nozzle arm 413 and the first nozzle 411 swing with respect to the support rod 415 as the axis. The first nozzle 411 may swing between the outside and the inside of the bowl 200.

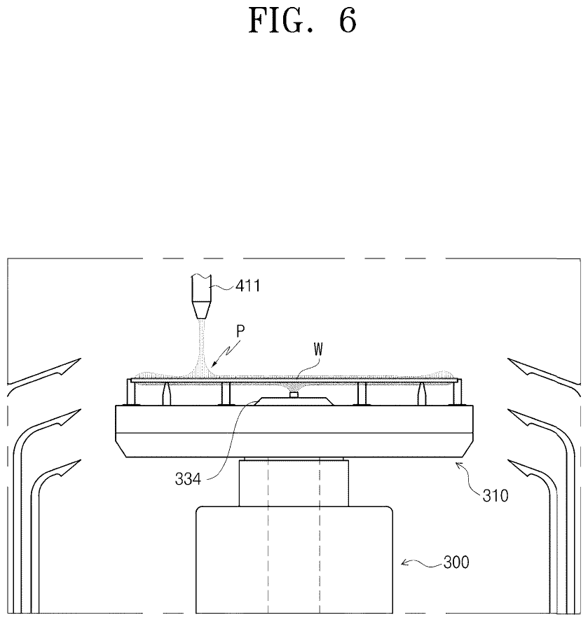

The first nozzle 411 may discharge heating fluid to an impact point P (see FIG. 6) that is closer to the edge than the center C of the substrate W. For example, when the substrate is a 300 mm wafer, the impact point P may be provided within a range of 15 to 75 mm spaced from the edge. The heating fluid may be discharged onto the non-patterned face of the substrate at a higher temperature than the etchant. For example, in order to maintain the same E/R value at different locations on the substrate, it is desirable that the temperature of the edge of the substrate is 1.7 to 3.7° C. higher than the temperature of the center of the substrate, and to this end, when the temperature of the etchant discharged to the patterned face of the substrate is 50° C., the temperature of the heating fluid discharged to the non-patterned face of the substrate may be 50+α° C.

Although not illustrated, the chamber 100 may be provided with a rinse solution supply unit for supplying a rinse solution to the substrate, and the rinse solution supply unit may be provided in substantially the same configuration as the heating fluid supply unit, which will not be described.

The controller 800 may control the substrate processing apparatus. The controller 800 may control the components of the process chamber to treat the substrate according to the setting process as described above. Further, the controller 800 may include a process controller formed of a microprocessor (computer) executing the control of the substrate processing apparatus, a user interface formed of a keyboard through which an operator performs a command input manipulation and the like for managing the substrate processing apparatus, a display for visualizing and displaying an operation situation of the substrate processing apparatus, or the like, and a storage unit in which a control program for executing the processing executed in the substrate processing apparatus under the control of the process controller or various data and a program, that is, a processing recipe, for executing processing on each configuration according to processing conditions are stored. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

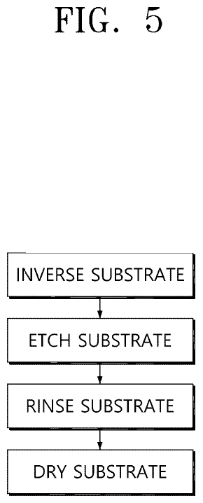

FIGS. 5 and 6 are flowcharts and diagrams illustrating a process of processing a substrate according to an exemplary embodiment of the present invention. A substrate processing method according to an exemplary embodiment of the present invention will be described with reference to FIGS. 5 and 6.

Prior to the etching process on the substrate, a substrate inversion process may be performed. The substrate inversion process is the process of inverting the substrate that has been loaded into the chamber 100 and loading the inverted substrate onto the support unit 300. The substrate is loaded into the chamber 100 and delivered to the inversion unit 700 (see FIG. 3), and the substrate is inverted 180 degrees by the inversion operation of the inversion unit 700. In this case, the patterned face of the substrate is facing down. The inverted substrate is placed on the support unit 300. In another example, the substrate may be loaded into the chamber after being inverted in another substrate processing apparatus.

When the substrate is placed on the support unit 300, a chemical solution processing process may be performed. In the chemical solution processing process (etching process), in the state where the substrate is rotated, the back nozzle spraying part 334 of the treatment solution supply unit 330 supplies the etchant to the patterned face of the substrate, and the first nozzle 411 of the heating fluid supply unit 410 supplies hot ultrapure water that is the heating fluid to the non-patterned face of the substrate. The time of supply of the heating fluid may be earlier or the same as the time of supply of the etchant. The etchant may be supplied at a high temperature (e.g., 50degrees Celsius), and the etchant may be discharged toward the center of the patterned face of the substrate.

The heating fluid (heated pure water) may be supplied at a higher temperature than the etchant. The heating fluid may be discharged to an impact point deviating from the center of the substrate such that the temperature of the edge region of the substrate is higher than the temperature of the center region of the substrate by a predetermined temperature. The support unit 300 may be rotated at 10 to 500 rpm during the chemical solution processing process.

When the etching process on the substrate is complete, a rinse process may be performed. In the rinse process, pure water may be supplied to the patterned face of the substrate through the back nozzle spraying part 334. In another example, the rinse process may be performed by inverting, by the inversion unit 700, the substrate so that the patterned face of the substrate faces up, placing the inverted substrate on the support unit 300, and discharging pure water from the upper portion of the substrate.

The substrate W may then be subjected to a drying process S400. The drying process may be spin drying, supercritical drying, or the like.

After the drying process, the substrate may be inverted by the inversion unit 700 and unloaded from the chamber 100.

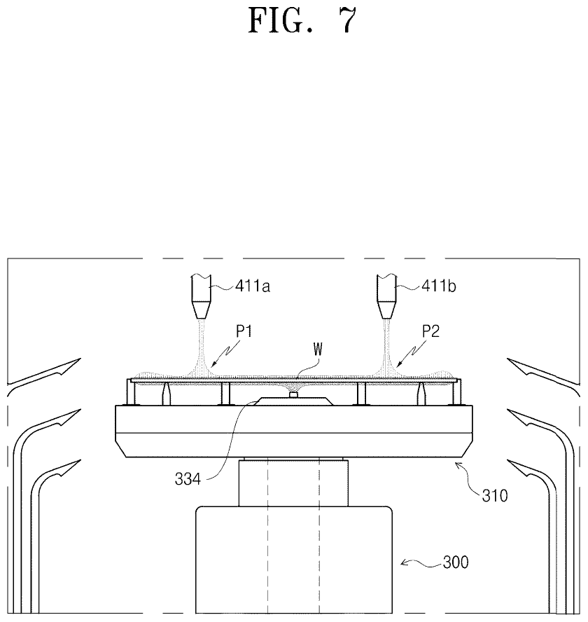

FIG. 7 is a diagram illustrating a modified example of the present invention.

As illustrated in FIG. 7, during the etching process on the substrate, the etchant may be discharged to a plurality of impact points deviating from the center of the substrate. For example, the etchant may be discharged through the first nozzle 411a and the second nozzle 411b to a first impact point P1 and a second impact point P2. The first impact point P1 and the second impact point P2 may be provided to be symmetrical with respect to the center C of the substrate. For example, when there are more than three impact points, the impact points may be provided equidistantly spaced with respect to the center of the substrate.

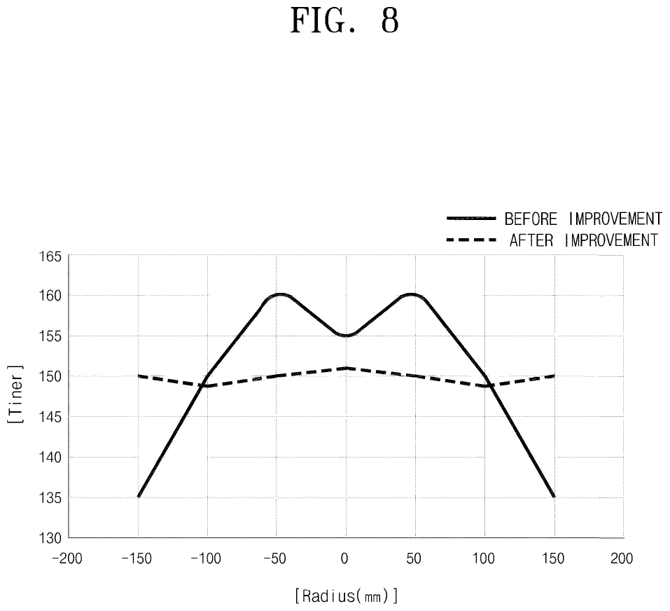

FIG. 8 is a graph illustrating the uniformity of etch rate (E/R Uniformity) through inverse supply.

Referring to FIG. 8, the present invention achieves temperature compensation at the edge of the substrate by placing the substrate on the support unit in an inverted state by the inversion unit, discharging a high-temperature etchant from under the substrate toward the patterned face, and discharging high-temperature pure water from the upper portion of the substrate to an impact point close to the edge. Thus, the temperature of the edge of the substrate is maintained at a predetermined temperature higher than the temperature of the center of the substrate, thereby improving the etching E/R dispersion compared to the previous improvement.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A substrate processing method comprising:
loading a substrate onto a support unit positioned in a processing space of a chamber so that a patterned face of the substrate faces down; and
rotating the substrate loaded onto the support unit, discharging an etchant for etching a thin film formed on the patterned face onto the patterned face of the substrate, and discharging a heating fluid onto a non-patterned face of the substrate.

2. The substrate processing method of claim 1, wherein the heating fluid is discharged to an impact point deviating from a center of the substrate such that a temperature of an edge region of the substrate is higher than a temperature of a center region of the substrate by a predetermined temperature, and the etchant is discharged onto a center of the substrate.

3. The substrate processing method of claim 2, wherein the impact point is spaced from an edge of the substrate.

4. The substrate processing method of claim 2, wherein the heating fluid is discharged onto the non-patterned face of the substrate at a predetermined temperature higher than a temperature of the etchant by a predetermined temperature.

5. The substrate processing method of claim 2, wherein the heating fluid is discharged to a plurality of impact points deviating from the center of the substrate, and the impact point is provided closer to an edge of the substrate than to a center of the substrate.

6. The substrate processing method of claim 5, wherein the plurality of impact points includes a first impact point and a second impact point, and the first impact point and the second impact point are provided to be symmetrical with respect to the center of the substrate.

7. The substrate processing method of claim 2, wherein the substrate is inverted by an inversion unit after being loaded into the chamber, and loaded onto the support unit.

8. The substrate processing method of claim 2, wherein the substrate is inverted by an inversion unit located in a separate chamber before being loaded into the chamber and loaded onto the support unit.

9. The substrate processing method of claim 2, wherein the thin film is a titanium nitride (TiN) film, the etchant includes hydrogen peroxide, and the heating unit includes high temperature pure water.

10-17. (canceled)

18. A substrate processing method comprising:
loading a substrate onto a support unit positioned in a processing space of a chamber so that a patterned face of a substrate faces down; and rotating the substrate loaded onto the support unit, discharging an etchant for etching a thin film on a patterned face of the substrate to the patterned face of the substrate, and discharging a heating fluid onto a non-patterned face of the substrate,
wherein the heating fluid is discharged to an impact point provided closer to an edge of the substrate than to a center of the substrate, the etchant is discharged to the center of the substrate, and the heating fluid has a temperature higher than the etchant.

19. The substrate processing method of claim 18, wherein the heating fluid is discharged to a plurality of impact points deviating from the center of the substrate, and the plurality of impact points includes a first impact point and a second impact point, and the first impact point and the second impact point are provided to be symmetrical with respect to the center of the substrate.

20. The substrate processing method of claim 19, wherein the substrate is inverted by an inversion unit after being loaded into the chamber and loaded onto the support unit, or is inverted by the inversion unit located in a separate chamber before being loaded into the chamber and loaded onto the support unit.
